(19) United States
(12) Patent Application Publication
(10) Pub. No.: US 2009/0001339 A1
(43) Pub. Date: Jan. 1, 2009

(54) Chemical Mechanical Polishing Slurry Composition for Polishing Phase-Change Memory Device and Method for Polishing Phase-Change Memory Device Using the Same

(76) Inventors: Tae Young LEE, Gunpo-si (KR); In Kyung Lee, Euiwang-si (KR); Byoung Ho Choi, Ansan-si (KR); Yong Soon Park, Gunpo-si (KR)

Correspondence Address: SUMMA, ALLAN & ADDITON, P.A., 11610 NORTH COMMUNITY HOUSE ROAD, SUITE 200, CHARLOTTE, NC, 28277, US

(21) Appl. No.: 11/967,439

(22) Filed: Dec. 31, 2007

(30) Foreign Application Priority Data
Jun. 29, 2007 (KR) 10-2007-0065872
Jun. 29, 2007 (KR) 10-2007-0065874

(51) Int. Cl. H01L 45/00; C09K 13/00; C09K 13/06

(52) U.S. Cl. 257/2; 252/79.1; 252/79.4; 438/102; 257/E45.002

(57) ABSTRACT

A slurry composition for chemical mechanical polishing (CMP) of a phase-change memory device is provided. The slurry composition comprises deionized water, a nitrogenous compound, and optionally abrasive particles, an oxidizing agent, or a combination thereof. The slurry composition can polish a phase-change memory device at a high rate, can achieve high polishing selectivity between a phase-change memory material and a polish stop layer (e.g., a silicon oxide film), and can minimize the occurrence of processing imperfections (e.g., dishing and erosion) to provide a high-quality polished surface. Further provided is a method for polishing a phase-change memory device using the slurry composition.

### CROSS-REFERENCE TO RELATED APPLICATIONS

This non-provisional application claims priority under 35 USC Section 119 from Korean Patent Application No. 10-2007-0065872, filed on Jun. 29, 2007, and Korean Patent Application No. 10-2007-0065874, filed on Jun. 29, 2007, the entire disclosure of each of which is hereby incorporated by reference.

### FIELD OF THE INVENTION

The present invention relates to a slurry composition for polishing a phase-change memory device used in a semiconductor manufacturing process. More specifically, the present invention relates to a slurry composition for chemical mechanical polishing (CMP) of a metal alloy or a chalcogenide included in a phase-change memory device, and a method for polishing a phase-change memory device using the slurry composition.

### BACKGROUND OF THE INVENTION

Demand for semiconductor memories has increased with expanding global markets for electronic devices, such as digital cameras, camcorders, MP3 players, digital multimedia broadcasting (DMB) receivers, navigation systems and mobile phones. In addition, there has been an increasing demand for high-capacity memories that are driven at high speed and reduced power consumption in terms of performance characteristics as compared to conventional memories. Under such circumstances, considerable research efforts have been made in developing next-generation memories that include the advantages and features inherent to dynamic random access memories (DRAMs), static random access memories (SRAMs) and flash memories. Phase-change RAMs (PRAMs), magnetoresistive RAMs (MRAMs), ferroelectric RAMs (FeRAMs) and polymer memories are currently considered next-generation memories. Of these, PRAMs possess the advantages of conventional highly integrated DRAMs, high-speed SRAMs and non-volatile NAND flash memories, and have excellent characteristics in terms of compatibility with conventional integration processes of complementary metal-oxide-semiconductor (C-MOS) field effect transistors (FETs). Based on these advantages, PRAMs have attracted more and more attention in recent years because of the greatest possibility of successful commercialization.

Since a paper reported by S. Lai (Intel) and T. Lowrey (Ovonyx) at the International Electronic Device Meeting (IEDM) in 2001, extensive research and development have been conducted on phase-change RAMs (PRAMs). Phase-change RAMs are non-volatile memories that use materials capable of inducing a reversible phase change between crystalline (low electrical resistance) and amorphous (high electrical resistance) phases due to Joule heating generated in response to an applied current or voltage to write data.

Metal alloys and chalcogenides are currently used as representative phase-change materials of PRAMs. Particularly, the composition of GeₓSb_{y}Te_{z} (GST), a chalcogenide, is now being investigated.

In CMP processes for phase-change materials of PRAM devices that are currently being developed, silicon oxide (SiO₂) is used to form polish stop layers. Polishing uniformity and surface imperfections (e.g., dishing and erosion) during polishing of patterned wafers are greatly affected by some processing factors, e.g., polishing and etch rates on phase-change materials, polishing uniformity of silicon oxide films and polishing selectivity between phase-change materials and silicon oxide films.

On the other hand, slurries for polishing aluminum, copper, tungsten and other metal wires are mainly employed in semiconductor manufacturing processes. Since these metal layer materials are composed of a single element, unlike phase-change materials of PRAM devices, they induce no phase change. Therefore, the conventional metal materials cannot be used for PRAM devices and cause a significant difference in layer characteristics.

Depending on the choice of an oxidizing agent, an abrasive, and other useful additives, a CMP slurry for polishing metal wires can be tailored to provide effective polishing on metal layers at desired polishing rates while minimizing surface imperfections, defects, corrosion, and erosion. Furthermore, the polishing slurry may be used to provide controlled polishing selectivities to other thin-film materials, such as titanium, titanium nitride, tantalum, tantalum nitride, oxides and the like.

Unlike conventional metal layers composed of a single element, such as copper (Cu) or tungsten (W), layers of phase-change memory devices to be polished are composed of materials consisting of particular elements, such as sulfur (S), selenium (Se), germanium (Ge), antimony (Sb), tellurium (Te), silver (Ag), indium (In), tin (Sn), gallium (Ga), and the like, in a specified ratio to undergo a reversible phase change between crystalline and amorphous phases. Since the characteristics of the materials to be polished are different from those of conventional metal layer materials, there exists a strong need to develop novel polishing compositions.

Ideal slurry compositions for polishing phase-change materials of phase-change memories (PRAMs) should meet the following requirements: i) the phase-change materials must be etched and polished at high rates; ii) the polishing selectivity between the phase-change materials and polish stop layers must be high; iii) dishing, erosion, pattern non-uniformity, imperfections (e.g., scratches, defects and corrosion), and the like must be minimized; and iv) there must be no change in the composition and phase of elements constituting the surface of the phase-change materials after polishing.

### SUMMARY OF THE INVENTION

The present invention provides a slurry composition for chemical mechanical polishing (CMP) of a phase-change memory device that can polish a phase-change memory device at a high rate, can achieve high polishing selectivity between a phase-change memory material and a polish stop layer (e.g., a silicon oxide film), and can minimize the occurrence of processing imperfections (e.g., dishing and erosion) to provide a high-quality polished surface; and a method for polishing a phase-change memory device using the CMP slurry composition.

The present invention further provides a slurry composition for chemical mechanical polishing of a phase-change memory device that can cause substantially no change in the composition or phase of a phase-change material before and after polishing, can minimize the occurrence of surface imperfections (e.g., scratches, defects, corrosion and polishing residues) to provide a clean polished surface, and can contain very small amounts of metal impurities to cause few or no environmental pollution problems after being disposed; and a method for polishing a phase-change memory device using the CMP slurry composition.

In accordance with one aspect of the present invention, there is provided a slurry composition for chemical mechanical polishing (CMP) of a phase-change memory device which comprises deionized water, a nitrogenous compound, and one or more additional components that can provide desired CMP characteristics to the slurry composition, such as abrasive particles, an oxidizing agent, or a combination of abrasive particles and an oxidizing agent.

The phase-change memory device can include a metal alloy or a chalcogenide.

The phase-change memory device can include at least one compound selected from InSe, Sb₂Te₃, GeTe, Ge₂Sb₂Te₅, InSbTe, GaSeTe, SnSb₂Te₄, InSbGe, AgInSbTe, (GeSn)SbTe, GeSb(SeTe) and Te₈₁Ge₁₅Sb₂S₂.

The nitrogenous compound can include at least one compound selected from an aliphatic amine, an aromatic amine, an ammonium salt and an ammonium base.

The aliphatic amine can be a primary amine, secondary amine or tertiary amine.

The aliphatic amine can have at least one alkyl or alcohol group.

The aliphatic amine can have at least one substituent containing one to seven carbon atoms.

The aliphatic amine can include a heterocyclic compound.

The heterocyclic compound can include a piperazine compound.

The ammonium salt or ammonium base can include at least one compound selected from tetramethylammonium hydroxide, tetraethylammonium hydroxide, tetrapropylammonium hydroxide, and salts derived therefrom.

The nitrogenous compound can be present in the slurry composition in an amount of about 0.001 to about 5% by weight, based on the total weight of the slurry composition.

In one embodiment of this aspect of the invention, the slurry compositions can include abrasive particles. The abrasive particles can include particles of at least one metal oxide selected from the group consisting of silica (SiO₂), alumina (Al₂O₃), ceria (CeO₂) and zirconia (ZrO₂), or synthetic polymer particles.

The abrasive particles can have an average primary particle diameter of about 1 to about 200 nm and an average specific surface area of about 10 to about 500 m²/g.

The abrasive particles can be present in the slurry composition in an amount of about 0.01 to about 30% by weight, based on the total weight of the slurry composition.

In another embodiment of this aspect of the invention, the CMP slurry composition can include an oxidizing agent.

The oxidizing agent can have a higher standard electrochemical redox potential than a phase-change material to be polished.

The oxidizing agent can include a per-compound, iron or an iron compound.

The per-compound can be a compound containing one or more peroxy groups (—O—O—) or a compound containing an element in its highest oxidation state.

The compound containing one or more peroxy groups (—O—O—) can include at least one compound selected from hydrogen peroxide, urea hydrogen peroxide, percarbonate, benzoyl peroxide, peracetic acid, di-t-butyl peroxide, monopersulfate (SO₅), dipersulfate (S₂O₈), and salts derived therefrom.

The compound containing an element in its highest oxidation state can include at least one compound selected from periodic acid, perbromic acid, perchloric acid, perboric acid, permanganate, and salts derived therefrom.

The iron or iron compound can include a metal iron or a compound containing iron in its molecular structure.

In exemplary embodiments of the invention, the oxidizing agent can include at least one compound selected from hydrogen peroxide, monopersulfates, dipersulfates, ionic iron compounds, and iron chelate compounds.

The oxidizing agent can be present in the slurry composition of the invention in an amount of about 0.01 to about 10% by weight, based on the total weight of the slurry composition.

In yet another embodiment of this aspect of the invention, the CMP slurry composition can include both abrasive particles and an oxidizing agent.

The slurry composition can have a pH of about 2 to about 10.

The CMP slurry composition can further comprise a pH-adjusting agent.

The pH-adjusting agent can include at least one acid selected from nitric acid, phosphoric acid, sulfuric acid, hydrochloric acid, and organic carboxylic acids having a pKa of 6 or less.

In accordance with another aspect of the present invention, there is provided a method for polishing a phase-change memory device using the CMP slurry composition.

A phase-change memory device can be fabricated by applying an insulating material to a semiconductor wafer to form an insulating layer, planarizing the insulating layer, patterning the planar insulating layer, and applying a phase-change material to the patterned insulating layer to form a phase-change material layer; and the CMP slurry composition can be brought into contact with the phase-change material layer to polish the phase-change material layer until the insulating layer is exposed.

The phase-change material layer can be polished by applying the CMP slurry composition to a rotating polishing pad and bringing the polishing pad into contact with the phase-change material layer under predetermined pressure conditions to polish portions of the phase-change material layer by a frictional force.

In yet another aspect of the present invention, there is provided a phase-change memory device polished by the polishing method.

### DETAILED DESCRIPTION OF THE INVENTION

The present invention now will be described more fully hereinafter in the following detailed description of the invention, in which some, but not all embodiments of the invention are described. Indeed, this invention may be embodied in many different forms and should not be construed as limited to the embodiments set forth herein; rather, these embodiments are provided so that this disclosure will satisfy applicable legal requirements.

The present invention provides a chemical mechanical polishing (CMP) slurry composition for polishing a phase-change memory device which comprises deionized water, a nitrogenous compound, and optionally one or more additional components that can provide desired CMP characteristics to the slurry composition, such as abrasive particles, an oxidizing agent, or a combination of abrasive particles and an oxidizing agent. Accordingly, in exemplary embodiments of the invention, the CMP slurry composition can include deionized water and a nitrogenous compound. In other exemplary embodiments of the invention, the CMP slurry composition can include deionized water; a nitrogenous compound; and abrasive particles. In other exemplary embodiments of the invention, the CMP slurry composition can include deionized water; a nitrogenous compound; and an oxidizing agent. In yet other exemplary embodiments of the invention, the CMP slurry composition can include deionized water; a nitrogenous compound; abrasive particles; and an oxidizing agent.

The phase-change memory device typically includes a metal alloy or a chalcogenide as a phase-change material that undergoes a reversible phase change between crystalline and amorphous phases.

Examples of suitable phase-change materials for use in the present invention include, but are not limited to: binary compounds, such as InSe, Sb₂Te₃ and GeTe; ternary compounds, such as Ge₂Sb₂Te₅, InSbTe, GaSeTe, SnSb₂Te₄ and InSbGe; and quaternary compounds, such as AgInSbTe, (GeSn)SbTe, GeSb(SeTe) and Te₈₁Ge₁₅Sb₂S₂.

The nitrogenous compound is a material that is effective in uniformly and rapidly polishing the phase-change material upon CMP processing and that is capable of reducing the occurrence of erosion and dishing in a pattern. The nitrogenous compound can be an aliphatic amine, an aromatic amine, an ammonium salt or an ammonium base, or a combination thereof. The nitrogenous compound can be one miscible with water.

The aliphatic amine may be a primary amine, secondary amine or tertiary amine. A mixture of two or more aliphatic amines may also be used.

The aliphatic amine may be unsubstituted or substituted and in exemplary embodiments can have at least one alkyl or alcohol group. An alkyl group can be useful in terms of polishing rate on the phase-change material. The aliphatic amine can have at least one substituent containing one to seven carbon atoms.

The aliphatic amine can be a heterocyclic compound such as piperazine. A combination of two or more aliphatic amines may be used.

There is no particular restriction on the kind of the ammonium salt or ammonium base, and at least one compound selected from tetramethylammonium hydroxide, tetraethylammonium hydroxide, tetrapropylammonium hydroxide and salts derived therefrom, and well as combinations thereof, can be used as the ammonium salt or ammonium base.

The nitrogenous compound can be present in the slurry composition in an amount of about 0.001 to about 5% by weight, for example about 0.005 to about 3% by weight, and as another example about 0.01 to about 1% by weight, based on the total weight of the slurry composition. The amount of the nitrogenous compound used can be determined taking into consideration the stimulatory effects of the nitrogenous compound on the polishing of the phase-change material, uniform polishing rate on the phase-change material, desirable surface characteristics and optimal pH maintenance.

The abrasive particles may be particles of at least one metal oxide selected from the group consisting of silica (SiO₂), alumina (Al₂O₃), ceria (CeO₂) and zirconia (ZrO₂), and the like, or synthetic polymer particles, or combinations thereof.

As the synthetic polymer particles, any known polymer particles may be suitably selected according to the kind of the device to be polished. For example, such polymer particles include abrasive particles composed of polymers only, abrasive particles composed of polymer-coated metal oxides, and abrasive particles composed of metal oxide-coated polymers.

The abrasive particles can have an average primary particle diameter of about 1 to about 200 nm and an average specific surface area of about 10 to about 500 m²/g. In exemplary embodiments of the invention, to provide certain dispersion stability and polishing performance, the abrasive particles can have an average primary particle diameter of about 5 to about 100 nm, for example about 10 to about 80 nm, and an average specific surface area of about 30 to about 300 m²/g, for example about 40 to about 250 m²/g.

The abrasive particles can be present in the slurry composition in an amount of about 0.01 to about 30% by weight, for example about 0.05 to about 20% by weight, and as another example about 0.1 to about 10% by weight, based on the total weight of the slurry composition.

The oxidizing agent can oxidize the surface layer of the phase-change material to an oxide or ions to facilitate the removal of the surface layer and can function to uniformly polish portions of the phase-change material within a pattern region until a polish stop layer (e.g., a silicon oxide film) is exposed to improve the surface roughness of the pattern. In addition, the use of the oxidizing agent can facilitate the removal of residues of the phase-change material present in the polish stop layer, thereby enabling more uniform polishing.

Any oxidizing agent may be used in the present invention so long as it has a higher standard electrochemical redox potential than the phase-change material to be polished. The oxidizing agent can be, for example, a per-compound, iron or an iron compound. The oxidizing agent may also be combined with one or more other oxidizing agents.

The term ‘per-compound’ as used herein refers to a compound containing one or more peroxy groups (—O—O—) or a compound containing an element in its highest oxidation state. Organic and inorganic per-compounds may be used in the present invention.

Examples of compounds containing one or more peroxy groups (—O—O—) include, but are not limited to, hydrogen peroxide, urea hydrogen peroxide, percarbonate, benzoyl peroxide, peracetic acid, di-t-butyl peroxide, monopersulfate (SO₅), dipersulfate (S₂O₈), and salts derived therefrom.

Examples of compounds containing an element in its highest oxidation state include, but are not limited to, periodic acid, perbromic acid, perchloric acid, perboric acid, permanganate, and salts derived therefrom.

The iron or iron compound may be metal iron or a compound containing iron in its molecular structure.

Non-limiting examples of suitable oxidizing agents for use in the present invention include hydrogen peroxide, monopersulfates, dipersulfates, ionic iron compounds, and iron chelate compounds. As used herein, the hydrogen peroxide is defined to include adducts obtained by previously reacting hydrogen peroxide with one or more other materials (e.g., a radical generating catalyst).

The hydrogen peroxide or its adduct can cause no environmental pollution and advantageously can function to clean the surface state of the phase-change material without any change in the composition of the phase-change material before and after polishing. The use of a monopersulfate, a dipersulfate, an ionic iron compound or an iron chelate compound as the oxidizing agent can be advantageous in that the phase-change material can be polished at a high rate.

The oxidizing agent may be present in the slurry compositions in an amount of about 0.01 to about 10% by weight, for example about 0.05 to about 5% by weight, and as another example about 0.1 to about 2% by weight, based on the total weight of the slurry composition. An amount of the oxidizing agent within these ranges can be useful to maintain optimal etching of the phase-change material.

The pH of the slurry composition can be adjusted to about 2 to about 10, for example about 2 to about 9, and as another example about 2 to about 5. The slurry composition of the present invention can further comprise a pH-adjusting agent to adjust the pH of the slurry composition to the range defined above. The pH-adjusting agent can include an inorganic acid selected from nitric acid, phosphoric acid, sulfuric acid and hydrochloric acid, or an organic carboxylic acid having a pKa of 6 or less, as well as combinations thereof.

The present invention also provides a method for polishing a phase-change memory device using the CMP slurry composition.

In exemplary embodiments of the present invention, the phase-change memory device can be fabricated by applying an insulating material to a semiconductor wafer to form an insulating layer, planarizing the insulating layer, patterning the planar insulating layer, and applying a phase-change material to the patterned insulating layer to form a phase-change material layer; and the CMP slurry composition can be brought into contact with the phase-change material layer to polish the phase-change material layer until the insulating layer is exposed.

In exemplary embodiments of the present invention, the phase-change material layer can be polished by applying the CMP slurry composition to a rotating polishing pad and bringing the polishing pad into contact with the phase-change material layer under predetermined pressure conditions to polish portions of the phase-change material layer by a frictional force. The pressure conditions can include those that are generally permissible in CMP applications.

The present invention also provides a phase-change memory device polished by the polishing method.

Hereinafter, the present invention will be explained in more detail with reference to the following examples. However, these examples are given for the purpose of illustration only and are not to be construed as limiting the scope of the invention. Further, the following examples are provided to illustrate exemplary CMP methods for planarizing a phase-change material.

### EXAMPLES

### Evaluation of Polishing of Blanket Wafers

### Examples 1-2 and Comparative Examples 1-2

Slurries having the compositions indicated in Table 1 are prepared. As abrasive particles, fumed silica particles having an average primary particle diameter of 15 nm and a specific surface area of 200 m²/g are used in an amount of 0.5% by weight with respect to the total weight of each of the slurry compositions. The fumed silica particles are homogeneously dispersed in deionized water. Triethylamine (TEA) is used as a nitrogenous compound in Examples 1 and 2, and hydrogen peroxide is used as an oxidizing agent in Example 2 and Comparative Example 2. Nitric acid is used to adjust the final pH of all slurry compositions to 2.5.

TABLE 1

| | | Triethylamine | Hydrogen | |
|---|---|---|---|---|
| Example No. | Silica (%) | (%) | peroxide (%) | pH |
| Example 1 | 0.5 | 0.2 | 0 | 2.5 |
| Example 2 | 0.5 | 0.2 | 1.0 | 2.5 |
| Comparative Example 1 | 0.5 | 0 | 0 | 2.5 |
| Comparative Example 2 | 0.5 | 0 | 1.0 | 2.5 |

After each of the slurry compositions is used to polish a blanket wafer deposited with a phase-change material under the following polishing conditions, the polishing performance of the slurry composition on the phase-change material is evaluated. The results are shown in Table 2.

As the phase-change material, Ge₂Sb₂Te₅ (GST), whose composition is germanium (Ge): antimony (Sb): tellurium (Te) (2:2:5), is used. The phase-change material is deposited on the blanket wafer by D.C magnetron sputtering to form a 5,000 Å-thick layer. A 15,000 Å-thick PETEOS silicon oxide film is used as a polish stop layer, and an IC1000/SubaIV CMP pad (Rodel Corp.) is used as a polishing pad. The phase-change material layer is polished using a 200 mm MIRRA polisher (manufactured by Applied Materials (AMAT)) at a down pressure of 1.5 psi, a slurry flow rate of 200 mL/min., a table speed of 100 rpm and a spindle speed of 100 rpm for one minute.

TABLE 2

| | Polishing characteristics | | | |
|---|---|---|---|---|
| | Polishing | | | |
| | rate | Polishing rate | Polishing | Polishing |
| | (Å/min) | (Å/min) | selectivity | non-uniformity |
| Example No. | on GST | on SiO₂ | (GST:SiO₂) | (%) on GST |
| Example 1 | 2,010 | 15 | 134:1 | 9 |
| Example 2 | 2,181 | 21 | 104:1 | 4 |
| Comparative | 137 | 15 | 9:1 | 39 |
| Example 1 | | | | |
| Comparative | 312 | 15 | 21:1 | 15 |
| Example 2 | | | | |

As can be seen from Table 2, the slurry compositions of Examples 1 and 2 comprising the nitrogenous compound show high polishing rates on the GST layer and greatly increased selectivities in polishing rate between the GST layer and the silicon oxide film in comparison with the slurry compositions of Comparative Examples 1 and 2. The addition of the oxidizing agent did not contribute to further improvement of the polishing rate on the GST layer in the slurry composition (Example 2) comprising a combination of the nitrogenous compound and the oxidizing agent, but markedly decreased the polishing non-uniformity on the GST layer.

The polishing non-uniformity is calculated by the following equation:

Non-uniformity (%)=(Standard deviation of polishing rate/Average of polishing rate)×100 (%)

The polishing rate is measured over the entire surface from the center of the wafer using a 49-point polar map method. A lower value of the non-uniformity means that the polishing is more uniformly conducted.

### Examples 3 to 6

Slurry compositions were prepared in the same manner as in Example 1 except that the kind and the content of the nitrogenous compound are varied as indicated in Table 3. The polishing characteristics (i.e. polishing rates) of the slurry compositions on the GST are compared according to the number of carbon atoms included in the alkyl groups of the substituted aliphatic amines, i.e. tertiary alkyl amines (trimethylamine, triethylamine and tripropylamine). The polishing rate of each of the slurry compositions on the blanket wafer deposited with the phase-change material is measured in the procedure described in Example 1. The results are shown in Table 3.

TABLE 3

| | | Amount (%) | |
|---|---|---|---|
| | Kind of nitrogenous | of nitrogenous | Polishing rate |
| Example No. | compound | compound | (Å/min.) on GST |
| Example 1 | Triethylamine | 0.2 | 2,010 |
| Example 3 | Triethylamine | 0.25 | 2,620 |
| Example 4 | Trimethylamine | 0.2 | 1,012 |
| Example 5 | Tripropylamine | 0.05 | 3,605 |
| Example 6 | Tripropylamine | 0.1 | 4,960 |

The results of Table 3 indicate that the slurry compositions of Examples 3 to 6 show higher polishing rates on the GST layer than those of Comparative Examples 1 and 2.

The polishing rates of the slurry compositions on the GST layer increased with increasing number of carbon atoms included in the alkyl groups of the substituted aliphatic amines (i.e. trialkylamines) and increasing content of the trialkylamines.

### Examples 7 to 11

Slurry compositions are prepared in the same manner as in Example 1 except that the kind and the content of the nitrogenous compound is varied as indicated in Table 4. The polishing rates of the slurry compositions on GST are compared according to the shapes of the nitrogenous compounds. The polishing rate of each of the slurry compositions on a blanket wafer deposited with GST as a phase-change material iswas measured in the procedure described in Example 1. The results are shown in Table 4.

TABLE 4

| | Kind of nitrogenous | | Polishing rate |
|---|---|---|---|
| Example No. | compound | Amount (%) | (Å/min.) on GST |
| Example 1 | Triethylamine | 0.2 | 2,010 |
| Example 7 | Diethylethanolamine | 0.2 | 1,683 |
| Example 8 | Diethanolamine | 0.2 | 941 |
| Example 9 | Triethanolamine | 0.2 | 910 |
| Example 10 | Piperazine | 0.2 | 1,007 |
| Example 11 | Tetraethylammonium | 0.2 | 2,589 |
| | hydroxide | | |

The results of Table 4 demonstrate that the slurry compositions of Examples 7 to 11 show higher polishing rates on the GST layer than those of Comparative Examples 1 and 2. Particularly, the slurry compositions comprising the aliphatic alkylamine or the ammonium base show better polishing results.

[Evaluation of Polishing on Patterned Wafers]

To evaluate the polishing performance of the slurry compositions on semiconductor patterns, patterned wafers are constructed by the following procedure:

Step 1: Deposition of silicon nitride (SiN) to a thickness of 850 Å

Step 2: Deposition of silicon dioxide (SiO₂) to a thickness of 1,500 Å

Step 3: Formation of pattern on the oxide film

Step 4: Deposition of phase-change material (Ge₂Sb₂Te₅) to a thickness of 2,000 Å

The silicon oxide film is used as a stop layer in the pattern region. The polishing performance of the compositions of Examples 1 to 3 on the patterned wafers is evaluated. The polishing rates of the compositions of Comparative Examples 1 and 2 on the GST are too low to evaluate the state of the patterns.

Evaluation is conducted on the patterned wafers under the same polishing conditions as described in Example 1 except that the polishing time is varied. After over polishing (30%) is performed following the optic end point detection (EPD) time measured using an EPD system, the pattern regions are observed for erosion, dishing and roughness. The results are shown in Table 5.

TABLE 5

| | | Edge over | | | Maximum |
|---|---|---|---|---|---|
| Example | Erosion | Erosion | Dishing | | Roughness |
| No. | (Å) | (EOE, Å) | (Å) | Residues | (Rₘₐₓ, Å) |
| Example 1 | 50 | Not observed | 68 | Small amounts | 120 |
| | | | | Observed | |
| Example 2 | 45 | 120 | 50 | Not observed | 20 |
| Example 3 | 60 | Not observed | 80 | Not observed | 80 |

After pattern polishing, the composition of Example 1 shows better results in terms of erosion, EOE and dishing evaluation. Residues are observed in only small amounts, which could be sufficiently removed by controlling the over-polishing time after the EPD.

No residue is left after pattern polishing using the composition of Example 2. The composition of Example 2 shows excellent performance in terms of maximum roughness in the pattern region. The edges of the pattern are slightly eroded, which is lower than the acceptable level (200 Å) and causes no problem.

The composition of Example 3 using a bit larger amount of the nitrogenous compound than the composition of Example 1 causes slightly increased erosion and dishing, but shows better results in terms of residue and maximum roughness evaluation.

It could be concluded from these results that the compositions of Examples 1 to 3 are suitable for GST polishing and exhibit excellent pattern polishing characteristics.

[Further Evaluation of Polishing of Blanket Wafers]

### Examples 12-16 and Comparative Examples 3-8

Slurries having the compositions indicated in Table 1A are prepared using deionized water containing no abrasive particles. Triethylamine (TEA) is used as a nitrogenous compound in Examples 12 to 16 and Comparative Example 3. The TEA content and the kind and content of oxidizing agents used are varied in the slurry compositions. Nitric acid is used to adjust the final pH of all slurry compositions to 3.5.

TABLE 1A

| | TEA | | Content of | |
|---|---|---|---|---|
| | Content | Kind of | oxidizing | |
| Example No. | (%) | oxidizing agent | agent (%) | pH |
| Example 12 | 0.2 | H₂O₂ | 0.5 | 3.5 |
| Example 13 | 0.5 | H₂O₂ | 1.0 | 3.5 |
| Example 14 | 0.2 | Ammonium | 1.0 | 3.5 |
| | | persulfate | | |
| Example 15 | 0.1 | Propylenediamine | 0.2 | 3.5 |
| | | tetraacetic acid-Fe | | |
| Example 16 | 0.1 | FeCl₃ | 0.2 | 3.5 |
| Comparative Example 3 | 0.2 | — | 0 | 3.5 |
| Comparative Example 4 | 0 | H₂O₂ | 0.5 | 3.5 |
| Comparative Example 5 | 0 | H₂O₂ | 1.0 | 3.5 |
| Comparative Example 6 | 0 | Ammonium | 1.0 | 3.5 |
| | | persulfate | | |
| Comparative Example 7 | 0 | Propylenediamine | 0.2 | 3.5 |
| | | tetraacetic acid-Fe | | |
| Comparative Example 8 | 0 | FeCl₃ | 0.2 | 3.5 |

After each of the slurry compositions is used to polish a blanket wafer deposited with a phase-change material under the following polishing conditions, the polishing performance of the slurry composition on the phase-change material is evaluated. The results are shown in Table 2A.

As the phase-change material, Ge₂Sb₂Te₅ (GST), whose composition is germanium (Ge): antimony (Sb): tellurium (Te) (2:2:5), is used. The phase-change material is deposited on the blanket wafer by D.C magnetron sputtering to form a 2,000 Å-thick layer. A 15,000 Å-thick PETEOS silicon oxide film is used as a polish stop layer, and an IC1000/SubaIV CMP pad (Rodel Corp.) is used as a polishing pad. The phase-change material layer is polished using a 200 mm MIRRA polisher (manufactured by Applied Materials (AMAT)) at a down pressure of 3.0 psi, a slurry flow rate of 200 mL/min., a table speed of 100 rpm and a spindle speed of 100 rpm for one minute.

TABLE 2A

| | Polishing Characteristics | | | |
|---|---|---|---|---|
| | Polishing | | | |
| | rate | Polishing rate | Polishing | Polishing |
| | (Å/min) | (Å/min) | selectivity | non-uniformity |
| Example No. | on GST | on SiO₂ | (GST:SiO₂) | (%) on GST |
| Example 12 | 1,450 | 12 | 120.8 | 8 |
| Example 13 | 1,793 | 16 | 112.1 | 9 |
| Example 14 | 1,860 | 14 | 132.8 | 7 |
| Example 15 | 1,653 | 15 | 124.0 | 6 |
| Example 16 | 1,784 | 16 | 111.5 | 7 |
| Comparative | 601 | 10 | 60.0 | 21 |
| Example 3 | | | | |
| Comparative | 510 | 8 | 63.7 | 34 |
| Example 4 | | | | |
| Comparative | 590 | 9 | 65.6 | 39 |
| Example 5 | | | | |
| Comparative | 910 | 12 | 75.8 | 18 |
| Example 6 | | | | |
| Comparative | 1,230 | 16 | 76.8 | 11 |
| Example 7 | | | | |
| Comparative | 1,312 | 15 | 87.5 | 12 |
| Example 8 | | | | |

As can be seen from Table 2A the slurry compositions of Examples 12 to 16 comprising a combination of the nitrogenous compound and the corresponding oxidizing agent show high polishing rates on the GST layer and greatly increased selectivities (>100) in polishing rate between the GST layer and the silicon oxide film in comparison with the slurry compositions of Comparative Examples 3 to 8. In addition, the slurry compositions of Examples 12 to 16 show lower polishing non-uniformities on the GST layer than the slurry compositions of Comparative Examples 3 to 8. Furthermore, since no abrasive particles are included in the slurry compositions of Examples 1 to 5, it is anticipated that the problem of surface contamination caused by abrasive particles can be largely avoid.

The polishing non-uniformity is calculated by the following equation:

Non-uniformity (%)=(Standard deviation of polishing rate/Average of polishing rate)×100 (%)

The polishing rate is measured over the entire surface from the center of the wafer using a 49-point polar map method. A lower value of the non-uniformity means that the polishing is more uniformly conducted.

### Examples 17 to 24

Slurry compositions are prepared in the same manner as in Example 15 except that the kind and the content of the nitrogenous compound are varied as indicated in Table 3A. The polishing characteristics (i.e. polishing rates) of the slurry compositions on the GST are compared according to the kind and the content of the nitrogenous compounds. The polishing rate of each of the slurry compositions on the blanket wafer deposited with the phase-change material is measured in the procedure described in Example 15. The results are shown in Table 3A.

TABLE 3A

| | | Amount (%) | |
|---|---|---|---|
| | Kind of nitrogenous | of nitrogenous | Polishing rate |
| Example No. | compound | compound | (Å/min.) on GST |
| Example 15 | Triethylamine | 0.1 | 1,653 |
| Example 17 | Diethylethanolamine | 0.1 | 1,510 |
| Example 18 | Diethanolamine | 0.1 | 1,200 |
| Example 19 | Diethanolamine | 0.5 | 1,550 |
| Example 20 | Triethanolamine | 0.1 | 1,100 |
| Example 21 | Triethanolamine | 0.5 | 1,450 |
| Example 22 | Piperazine | 0.1 | 1,210 |
| Example 23 | Piperazine | 0.5 | 1,610 |
| Example 24 | Tetraethylammonium | 0.1 | 1,785 |
| | hydroxide | | |

The results of Table 3A demonstrate that the slurry compositions comprising the aliphatic alkylamine or the ammonium base show higher polishing rates on the GST layer than those comprising the aliphatic amine substituted with alcohol groups.

[Further Evaluation of Polishing on Patterned Wafers]

To actually evaluate the polishing performance of the slurry compositions on semiconductor patterns, patterned wafers are constructed by the following procedure:

Step 1: Deposition of silicon nitride (SiN) to a thickness of 850 Å

Step 2: Deposition of silicon dioxide (SiO₂) to a thickness of 1,500 Å

Step 3: Formation of pattern on the oxide film

Step 4: Deposition of phase-change material (Ge₂Sb₂Te₅) to a thickness of 2,000 Å

The silicon oxide film is used as a stop layer in the pattern region. The polishing performance of the compositions of Examples 13 to 15 and Comparative Examples 4 to 8 on the patterned wafers is evaluated.

Evaluation is conducted on the patterned wafers under the same polishing conditions as described in Example 12 except that the polishing time is varied. After over polishing (50%) is performed following the optic end point detection (EPD) time measured using an EPD system, the pattern regions are observed for erosion, dishing and roughness. The results are shown in Table 4A.

TABLE 4A

| | | Edge over | | | Maximum |
|---|---|---|---|---|---|
| | Erosion | Erosion | Dishing | | Roughness |
| Example No. | (Å) | (EOE, Å) | (Å) | Residues | (Rₘₐₓ, Å) |
| Example 13 | 100 | 20 | 42 | Not observed | 43 |
| Example 14 | 150 | 35 | 50 | Not observed | 52 |
| Example 15 | 60 | 10 | 24 | Not observed | 32 |
| Comparative | 300 | 250 | 180 | Observed | 210 |
| Example 4 | | | | | |
| Comparative | 400 | 250 | 190 | Observed | 200 |
| Example 5 | | | | | |
| Comparative | 350 | 200 | 160 | Observed | 180 |
| Example 6 | | | | | |
| Comparative | 200 | 46 | 80 | Not observed | 90 |
| Example 7 | | | | | |
| Comparative | 200 | 50 | 82 | Not observed | 100 |
| Example 8 | | | | | |

Table 4A demonstrates that the slurry compositions of Examples 13 to 15 comprising a nitrogenous compound and an oxidizing agent show much better results in terms of erosion, EOE, dishing, residue and maximum roughness evaluations than those of Comparative Examples 4 to 8.

As apparent from the above description, the present invention provides a CMP slurry composition for polishing a phase-change memory device and a method for polishing a phase-change memory device using the CMP slurry composition. The slurry composition of the present invention can polish a phase-change memory device at a high rate, can achieve high polishing selectivity between a phase-change memory material and a polish stop layer (e.g., a silicon oxide film), and can minimize the occurrence of processing imperfections (e.g., dishing and erosion) to provide a high-quality polished surface.

After pattern polishing, the compositions of the invention can show better results in terms of erosion, EOE and dishing evaluation. In exemplary embodiments, the resultant phase-change memory device can include a metal alloy or a chalcogenide layer exhibiting a maximum erosion of 175 Å, and/or a maximum edge over erosion of about 150 Å, and/or a dishing maximum of about 100 Å, and/or a maximum roughness (Rₘₐₓ) of about 150 Å, for example, a maximum erosion of 150 Å, and/or a maximum edge over erosion of about 120 Å, and/or a dishing maximum of about 80 Å, and/or a maximum roughness (Rₘₐₓ) of about 120 Å.

Many modifications and other embodiments of the invention will come to mind to one skilled in the art to which this invention pertains having the benefit of the teachings presented in the foregoing descriptions. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation, the scope of the invention being defined in the claims.

What is claimed is:

1. A slurry composition for chemical mechanical polishing (CMP) of a phase-change memory device, comprising deionized water and a nitrogenous compound.

2. The slurry composition according to claim 1, wherein the phase-change memory device comprises a metal alloy or a chalcogenide.

3. The slurry composition according to claim 2, wherein the phase-change memory device comprises at least one compound selected from InSe, Sb₂Te₃, GeTe, Ge₂Sb₂Te₅, InSbTe, GaSeTe, SnSb₂Te₄, InSbGe, AgInSbTe, (GeSn)SbTe, GeSb(SeTe) or Te₈₁Ge₁₅Sb₂S₂.

4. The slurry composition according to claim 1, wherein the nitrogenous compound comprises at least one compound selected from aliphatic amines, aromatic amines, ammonium salts, ammonium bases, or a combination thereof.

5. The slurry composition according to claim 4, wherein the aliphatic amine comprises a primary amine, secondary amine or tertiary amine.

6. The slurry composition according to claim 5, wherein the aliphatic amine comprises a secondary amine or tertiary amine.

7. The slurry composition according to claim 5, wherein the aliphatic amine comprises at least one alkyl or alcohol group.

8. The slurry composition according to claim 5, wherein the aliphatic amine comprises at least one alkyl group.

9. The slurry composition according to claim 5, wherein the aliphatic amine comprises at least one substituent containing one to seven carbon atoms.

10. The slurry composition according to claim 5, wherein the aliphatic amine comprises a heterocyclic compound.

11. The slurry composition according to claim 10, wherein the heterocyclic compound comprises a piperazine compound.

12. The slurry composition according to claim 5, wherein the ammonium salt or ammonium base comprises at least one compound selected from tetramethylammonium hydroxide, tetraethylammonium hydroxide, tetrapropylammonium hydroxide, salts derived therefrom, or a combination thereof.

13. The slurry composition according to claim 1, wherein the nitrogenous compound is present in an amount of about 0.001 to about 5% by weight, based on the total weight of the slurry composition.

14. The slurry composition according to claim 1, further comprising abrasive particles.

15. The slurry composition according to claim 14, wherein the abrasive particles comprise particles of at least one metal oxide selected from the group consisting of silica (SiO₂), alumina (Al₂O₃), ceria (CeO₂) and zirconia (ZrO₂), or synthetic polymer particles, or combinations thereof.

16. The slurry composition according to claim 14, wherein the abrasive particles have an average primary particle diameter of about 1 to about 200 nm and an average specific surface area of about 10 to about 500 m²/g.

17. The slurry composition according to claim 14, wherein the abrasive particles are present in an amount of about 0.01 to about 30% by weight, based on the total weight of the slurry composition.

18. The slurry composition according to claim 1, further comprising an oxidizing agent.

19. The slurry composition according to claim 18, wherein the oxidizing agent has a higher standard electrochemical redox potential than a phase-change material of the phase-change memory device.

20. The slurry composition according to claim 18, wherein the oxidizing agent comprises a per-compound, iron or an iron compound.

21. The slurry composition according to claim 18, wherein the oxidizing agent comprises a per-compound.

22. The slurry composition according to claim 20, wherein the per-compound is a compound containing one or more peroxy groups (—O—O—) or a compound containing an element in its highest oxidation state.

23. The slurry composition according to claim 20, wherein the per-compound is a compound containing one or more peroxy groups (—O—O—).

24. The slurry composition according to claim 22, wherein the compound containing one or more peroxy groups (—O—O—) comprises at least one compound selected from hydrogen peroxide, urea hydrogen peroxide, percarbonate, benzoyl peroxide, peracetic acid, di-t-butyl peroxide, monopersulfate (SO₅), dipersulfate (S₂O₈), or salts derived therefrom, or a combination thereof.

25. The slurry composition according to claim 22, wherein the compound containing an element in its highest oxidation state comprises at least one compound selected from periodic acid, perbromic acid, perchloric acid, perboric acid, permanganate, or salts derived therefrom, or a combination thereof.

26. The slurry composition according to claim 20, wherein the iron or iron compound comprises metal iron or a compound containing iron in its molecular structure.

27. The slurry composition according to claim 18, wherein the oxidizing agent comprises at least one compound selected from hydrogen peroxide, monopersulfates, dipersulfates, ionic iron compounds, iron chelate compounds, or a combination thereof.

28. The slurry composition according to claim 18, wherein the oxidizing agent comprises hydrogen peroxide.

29. The slurry composition according to claim 18, wherein the oxidizing agent is present in an amount of about 0.01 to about 10% by weight, based on the total weight of the slurry composition.

30. The slurry composition according to claim 1, further comprising abrasive particles and an oxidizing agent.

31. The slurry composition according to claim 1, wherein the slurry composition has a pH of 2 to 10.

32. The slurry composition according to claim 1, further comprising a pH-adjusting agent.

33. The slurry composition according to claim 30, wherein the pH-adjusting agent includes at least one acid selected from nitric acid, phosphoric acid, sulfuric acid, hydrochloric acid, organic carboxylic acids having a pKa of 6 or less, or a combination thereof.

34. A method for polishing a phase-change memory device comprising a phase-change material layer, wherein the method comprises contacting said phase-change material layer with a CMP slurry composition comprising deionized water and a nitrogenous compound.

35. The method according to claim 34, wherein the CMP slurry composition further comprises abrasive particles.

36. The method according to claim 34, wherein the CMP slurry composition further comprises an oxidizing agent.

37. The method according to claim 34, wherein the CMP slurry composition further comprises abrasive particles and an oxidizing agent.

38. The method according to claim 34, wherein the phase-change memory device is fabricated by applying an insulating material to a semiconductor wafer to form an insulating layer, planarizing the insulating layer, patterning the planar insulating layer, and applying a phase-change material to the patterned insulating layer to form a phase-change material layer; and the CMP slurry composition is brought into contact with the phase-change material layer to polish the phase-change material layer until the insulating layer is exposed.

39. The method according to claim 38, wherein the phase-change material layer is polished by applying the CMP slurry composition to a rotating polishing pad and bringing the polishing pad into contact with the phase-change material layer under predetermined pressure conditions to polish portions of the phase-change material layer by a frictional force.

40. A phase-change memory device polished by the method according to claim 34.

41. A phase-change memory device comprising a metal alloy or a chalcogenide, wherein the metal alloy or chalogenide exhibits a maximum erosion of 175 Å, a maximum edge over erosion of about 150 Å, a dishing maximum of about 100 Å, and a maximum roughness (Rₘₐₓ) of about 150 Å.

42. The phase-change memory device according to claim 41, wherein the metal alloy or chalogenide exhibits a maximum erosion of 150 Å, a maximum edge over erosion of about 120 Å, a dishing maximum of about 80 Å, and a maximum roughness (Rₘₐₓ) of about 120 Å.

43. The phase-change memory device according to claim 41, wherein the phase-change memory device comprises at least one compound selected from InSe, Sb₂Te₃, GeTe, Ge₂Sb₂Te₅, InSbTe, GaSeTe, SnSb₂Te₄, InSbGe, AgInSbTe, (GeSn)SbTe, GeSb(SeTe) or Te₈₁Ge₁₅Sb₂S₂.
